(19) United States
(12) Patent Application Publication
(10) Pub. No.: US 2016/0111245 A1
(43) Pub. Date: Apr. 21, 2016

(54) ELECTRODE ASSEMBLY HAVING PIERCE ELECTRODES FOR CONTROLLING SPACE CHARGE EFFECTS

(71) Applicant: Advanced Ion Beam Technology, Inc., Hsin-Chu (TW)

(72) Inventors: Kourosh SAADATMAND, Danvers, MA (US); Nicholas WHITE, Fremont, CA (US)

(21) Appl. No.: 14/519,080

(22) Filed: Oct. 20, 2014

(51) Int. Cl. H01J 37/147; H01J 37/317; H05H 5/04

(52) U.S. Cl. CPC H01J 37/147; H05H 5/04; H01J 37/3172; H01J 2237/047

(57) ABSTRACT

An electrode assembly for accelerating or decelerating an ion beam is provided. In one example, the electrode assembly may include a pair of exit electrodes adjacent to an exit opening of the electrode assembly. The pair of exit electrodes may be positioned on opposite sides of a first plane aligned with a first dimension of the exit opening. A pair of pierce electrodes may be adjacent to the pair of exit electrodes. The pair of pierce electrodes may be positioned on opposite sides of a second plane aligned with a second dimension of the exit opening. The second dimension of the exit opening may be perpendicular to the first dimension of the exit opening. Each pierce electrode may include an angled surface positioned such that a dimension of the angled surface forms an angle of between 40 and 80 degrees with respect to the second plane.

### BACKGROUND

1. Field

The present disclosure relates generally to ion implantation, and more particularly, to an electrode assembly having pierce electrodes for controlling space charge effects in ion implantation.

2. Related Art

In semiconductor device fabrication, the electrical properties of materials may be modified through a process known as ion implantation. Typically, ions may be generated at an ion source, and extracted to form an ion beam. Further, the ion beam may be accelerated or decelerated to a desired energy level prior to impacting the work piece (e.g., semiconductor wafer). The energy of the ion beam may determine the depth of penetration of the ions at the target material, and thus the energy may be controlled based on a desired penetration depth.

During ion implantation, the ion beam may be accelerated or decelerated by means of an electrode assembly to control the energy of the ion beam. As the ion beam exits the electrode assembly, the ion beam may be susceptible to space charge effects, and more specifically, space charge blow-up. Under such conditions, ions within the ion beam may repel each other, thereby resulting in a disruption of the shape, angle, and uniformity of the ion beam. Space charge effects may be especially prevalent during high-current, low-energy ion implantation conditions. In particular, the ion beam may be decelerated through the electrode assembly such that the ion beam exits the electrode assembly having high current and low energy. Under these conditions, the repulsive forces between ions may be high due to the high density of ions in the ion beam while the momentum keeping ions traveling in a desired trajectory is low. This may cause the ion beam to diverge significantly as it exits the electrode assembly, thereby resulting in an unfocused ion beam that may be undesirable for use in semiconductor fabrication.

### BRIEF SUMMARY

An electrode assembly for accelerating or decelerating an ion beam is disclosed. In one example, the electrode assembly may include an ion beam path extending from a first opening of the electrode assembly to a second opening of the electrode assembly. The first opening and the second opening may be disposed on opposite sides of the electrode assembly. A pair of exit electrodes may define a portion of the ion beam path adjacent to the second opening. The pair of exit electrodes may be positioned on opposite sides of a first plane that is aligned with a first dimension of the second opening. A pair of pierce electrodes may define a portion of the ion beam path adjacent to the pair of exit electrodes. The pair of pierce electrodes may be positioned on opposite sides of a second plane aligned with a second dimension of the second opening. The second dimension of the second opening may be perpendicular to the first dimension of the second opening. Each pierce electrode of the pair of pierce electrodes may have an angled surface facing the ion beam path. The angled surface of each pierce electrode may be positioned such that a dimension of the angled surface of each pierce electrode forms an angle with respect to the second plane.

### BRIEF DESCRIPTION OF THE DRAWINGS

FIG. 1A illustrates a cross-sectional, two-dimensional view of an exemplary electrode assembly having pierce electrodes.

FIG. 1B illustrates a cross-sectional, three-dimensional perspective view of an exemplary electrode assembly having pierce electrodes.

FIG. 2 illustrates an angled top-down perspective view of a portion of an exemplary electrode assembly having pierce electrodes.

FIG. 3 illustrates a perspective view of an exemplary pierce electrode.

FIG. 4A illustrates an angled top-down perspective view of an ion beam passing through a portion of an exemplary electrode assembly having pierce electrodes.

FIG. 4B illustrates an exemplary ion beam profile of an ion beam after exiting an electrode assembly having pierce electrodes.

FIG. 5A illustrates an angled top-down perspective view of an ion beam passing through a portion of an exemplary electrode assembly having pierce electrodes.

FIG. 5B illustrates an exemplary ion beam profile of an ion beam after exiting an electrode assembly having pierce electrodes.

FIG. 6 illustrates an angled top-down perspective view of an ion beam passing through a portion of an exemplary electrode assembly without pierce electrodes.

FIGS. 7A-B illustrate an exemplary ion implantation system implementing an electrode assembly having pierce electrodes.

FIG. 8 illustrates an exemplary ion implantation process using an ion implantation system implementing an electrode assembly having pierce electrodes.

### DETAILED DESCRIPTION

The following description is presented to enable a person of ordinary skill in the art to make and use the various embodiments. Descriptions of specific systems, devices, methods, and applications are provided only as examples. Various modifications to the examples described herein will be readily apparent to those of ordinary skill in the art, and the general principles defined herein may be applied to other examples and applications without departing from the spirit and scope of the various embodiments. Thus, the various embodiments are not intended to be limited to the examples described herein and shown, but are to be accorded the scope consistent with the claims.

As described above, an ion beam may be susceptible to space charge effects at the exit of an electrode assembly. In the present disclosure, various examples of an electrode assembly having pierce electrodes for controlling such space charge effects are described. In one example, the electrode assembly may include a pair of exit electrodes adjacent to an exit opening of the electrode assembly. The pair of exit electrodes may be positioned on opposite sides of a horizontal reference plane aligned with a first dimension of the exit opening. A pair of pierce electrodes may be adjacent to the pair of exit electrodes. The pair of pierce electrodes may be positioned on opposite sides of a vertical reference plane aligned with a second dimension of the exit opening. The second dimension of the exit opening may be perpendicular to the first dimension of the exit opening. Each pierce electrode may include an angled surface positioned such that a dimension of the angled surface forms an angle of between 40 and 80 degrees with respect to the second plane. An ion beam traversing the electrode assembly may pass between the pair of pierce electrodes before exiting the electrode assembly via the pair of exit electrodes. The pair of pierce electrodes may control space charge effects by generating a suitable electric field along the boundary of the ion beam, thereby resisting the divergence of the ion beam. In this way, the ion beam may be collimated as it exits the electrode assembly.

Conventionally, pierce electrodes may be implemented as extraction electrodes to extract a collimated electron beam from an electron source. The electron source may contain a pool of ultra-low energy electrons (e.g., less than 20 eV). During the extraction of an electron beam, a potential difference may be applied between the extraction electrodes and the electron source to extract electrons from the electron source and accelerate the electrons to a desired energy. For such extraction electrodes, a unique solution may be derived to determine the shape and position of the extraction electrodes. However, this solution for extraction electrodes may not be applicable to the pierce electrodes implemented in an electrode assembly of an ion implantation system. This may be because ions used in ion implantation have mass-to-charge ratios that are significantly greater than that of electrons. Further, unlike an electron beam, the ion beam of an ion implantation system may include various ion species having different masses. Therefore, the shape and position of extraction electrodes used in extracting an electron beam may not be suitably implemented in an electrode assembly of an ion implantation system. In fact, implementing such extraction electrodes in an electrode assembly of an ion implantation system may yield undesirable results.

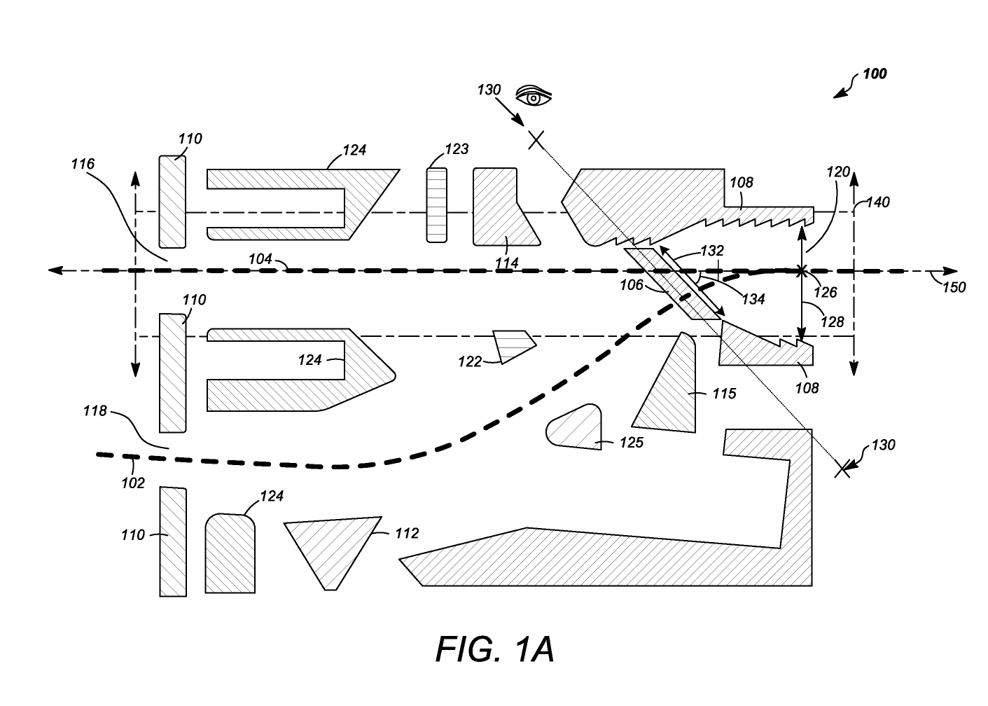

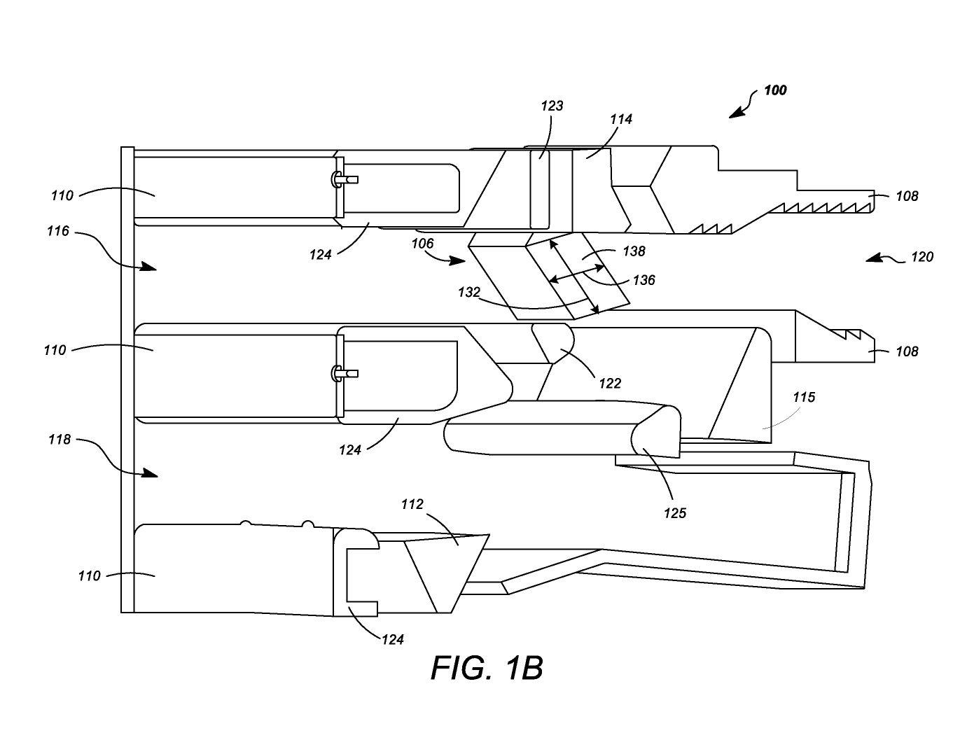

FIGS. 1A-B illustrate electrode assembly 100 having pierce electrodes, according to various examples. Specifically, FIG. 1A illustrates a cross-sectional two-dimensional view of electrode assembly 100 and FIG. 1B illustrates a cross-sectional three-dimensional perspective view of electrode assembly 100. Electrode assembly 100 may be configured to accelerate and/or decelerate an ion beam to control the energy of the ion beam. As shown in FIG. 1A, electrode assembly 100 may include ion beam paths 102 and 104 along which an ion beam may traverse electrode assembly 100. Ion beam path 102 may be curvilinear and may extend from opening 118 to opening 120 while ion beam path 104 may be approximately straight and may extend from opening 116 to opening 120. In some examples, opening 116 may be aligned with respect to opening 120 such that ion beam path 104 has a straight trajectory that is approximately parallel to horizontal reference plane 150. Openings 116 and 118 may be referred to as entrance openings while opening 120 may be referred to as an exit opening. It should be recognized that in other examples, the shape and trajectory of ion beam paths 102 and 104 may vary.

Electrode assembly 100 may include multiple electrodes for manipulating the ion beam as the ion beam travels along ion beam path 102 or 104. In the present example, the electrodes of electrode assembly 100 may be configured to decelerate the ion beam as the ion beam travels along ion beam path 102. The ion beam may thus enter opening 118 at an initial energy and exit opening 120 at a final energy that is lower than the initial energy. Further, in this example, the electrodes of electrode assembly 100 may be configured to accelerate the ion beam or allow the ion beam to drift at constant velocity as the ion beam travels along ion beam path 104. Thus, the ion beam may enter opening 118 at an initial energy and may exit opening 120 at a final energy that is equal or greater than the initial energy. It should be recognized that, in other examples, the electrode assembly 100 may be configured to accelerate the ion beam as the ion beam travels along ion beam path 102 or decelerate the ion beam as the ion beam travels along ion beam path 104.

Electrode assembly 100 may include a pair of exit electrodes 108 that at least partially defines opening 120. In particular, as shown in FIGS. 1A-B, exit electrodes 108 may define a portion of ion beam path 102 or 104 adjacent to opening 120 and may be positioned on opposite sides of horizontal reference plane 150. Horizontal reference plane 150 may be aligned with first dimension 126 of opening 120. First dimension 126 may be represented by the symbol X in FIG. 1A. Horizontal reference plane 150 and first dimension 126 of opening 120 may both be perpendicular to the plane of the drawing in FIG. 1A.

Exit electrodes 108 may be the final set of electrodes of electrode assembly 100 through which the ion beam passes prior to exiting electrode assembly 100. Exit electrodes 108 may be coupled to a ground potential and thus may be known as ground electrodes. In some examples, the region between exit electrodes 108 may be substantially or entirely free of any electric field. More specifically, the region between pierce electrodes 106 and opening 120 may be substantially or entirely free of any electric field. Therefore, in this region, the ion beam may not be controlled or manipulated by any electric fields. Ion beams having low energy and high current may thus be more susceptible to space charge effects in this region. In the present example, electrode assembly 100 may include a pair of pierce electrodes 106 for reducing space charge effects in this region. Pierce electrodes 106 may at least partially offset space charge effects by generating a suitable electric field along the boundary of the ion beam to prevent the ion beam from diverging. As shown in FIGS. 1A-B, pierce electrodes 106 may define a portion of ion beam path 102 or 104 adjacent to exit electrodes 108 and may be positioned on opposite sides of vertical reference plane 140. Vertical reference plane 140 may be aligned with second dimension 128 of second opening 120. Second dimension 128 may be perpendicular to first dimension 126 of opening 120. Vertical reference plane 140 may be parallel to the plane of the drawing in FIG. 1A and thus may be perpendicular to horizontal reference plane 150.

To effectively control space charge effects in the region between exit electrodes 108, it may be desirable to position pierce electrodes 106 in close proximity to exit electrodes 108. In some examples, pierce electrodes 106 may be positioned adjacent to exit electrodes 108 such that no electrode of electrode assembly 100 is positioned between pierce electrodes 106 and exit electrodes 108. The ion beam may thus pass through pierce electrodes 106 immediately prior to entering exit electrodes 108. In some examples, pierce electrodes 106 may be positioned at the boundary between a substantially electric field free zone of exit electrodes 108 and an electric field zone generated by other electrodes (e.g., electrodes 112, 114, 122, 123, etc.) of electrode assembly 100. In other examples, pierce electrodes 106 may be positioned as close as possible to exit electrodes 108 while still maintaining sufficient distance to prevent electrical arcing or shorting from occurring when a potential difference of 20 kV is applied between exit electrodes 108 and pierce electrodes 106. In a specific example, pierce electrodes 106 may be positioned between 2 millimeters and 5 millimeters from exit electrodes 108.

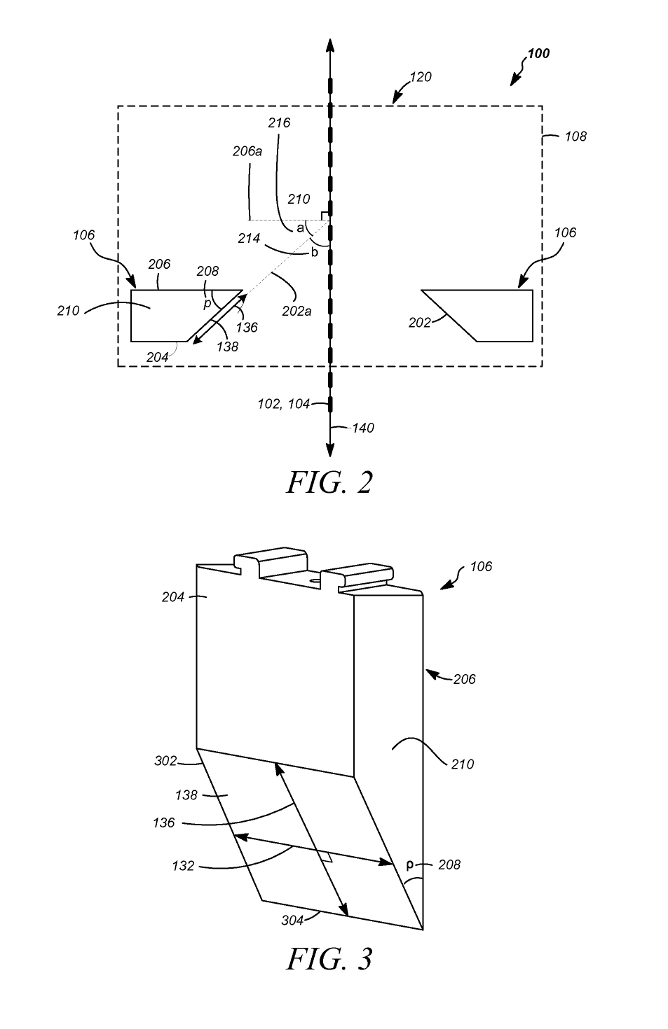

As shown in FIG. 1B, each pierce electrode 106 may include angled surface 138 facing ion beam paths 102 and 104. Angled surface 138 may have first dimension 136 that is perpendicular to second dimension 132. The position of angled surface 138 relative to ion beam paths 102 and 104 is more clearly depicted in FIG. 2. FIG. 2 illustrates an angled top-down perspective view of a portion of electrode assembly 100, according to various examples. The angled top-down perspective view may correspond to view angle 130 depicted in FIG. 1A. For simplicity, only a portion of electrode assembly 100 is depicted in FIG. 2. As shown, pierce electrodes 106 may be disposed on opposite sides of ion beam paths 102 and 104 with angled surface 138 of each pierce electrode facing ion beam paths 102 and 104. Angled surface 138 of each pierce electrode 106 may be positioned such that ion beam paths 102 and 104 gradually narrow between pierce electrodes 106 toward opening 120. Further, angled surface 138 of each pierce electrode 106 may be positioned such that first dimension 136 of angled surface 138 forms angle b 214 with vertical reference plane 140. In FIG. 2, vertical reference plane 140 may be perpendicular to the plane of the drawing. Angle b 214 may be such that a suitable electric field can be generated by pierce electrodes 106 along the boundary of the ion beam to resist divergence of the ion beam between exit electrodes 108. In some examples, angle b 214 may be between 40 and 85 degrees. In some examples, angle b 214 may be between 60 and 80 degrees. In some examples, angle b 214 may be between 65 and 75 degrees. In some examples, angle b 214 may be between 50 and 70 degrees. In some examples, angle b 214 may be between 0 and 45 degrees. In some examples, angle b 214 may be between 0 and 90 degrees. In a specific example, angle b 214 may be 70 degrees.

FIG. 3 illustrates a perspective view of pierce electrode 106, according to various examples. In this example, pierce electrode 106 may have a trapezoidal configuration. Angled surface 138 may be a rectangular surface having first dimension 136 and second dimension 132. First dimension 136 may be parallel to edge 302 of pierce electrode 106 and second dimension 132 may be parallel to edge 304 of pierce electrode 106. First dimension 136 and second dimension 132 may be orthogonal to each other. Angled surface 138 may form angle p 208 with respect to surface 206. Angle p 208 may be known as the pierce angle.

Although in the present example, pierce electrodes 106 may have a trapezoidal configuration, it should be recognized that the shape of pierce electrodes 106 may vary. For example, pierce electrode 106 may comprise any configuration having angled surface 138 positioned such that first dimension 136 of angled surface 138 forms angle b 214 with respect to vertical reference plane 140. In some examples, the pierce electrodes may have a triangular configuration. In other examples, electrodes may include a planar angled surface mounted on a supporting structure. The planar angled surface may be positioned similar to angled surface 138 described above. In addition, it should be recognized that the shape of angled surface 138 may vary. For example, angled surface 138 may be circular, square, or irregularly shaped. Further, in some examples, angled surface 138 may not be planar. For instance, in some examples, angled surface 138 may be concave or convex.

Returning now to FIG. 2, pierce electrodes 106 may be positioned such that surface 206 of each pierce electrode is orthogonal to vertical reference plane 140. As described above, first dimension 136 of angled surface 138 may form angle b 214 with vertical reference plane 140. More precisely, first dimension 136 may be extrapolated to intersect vertical reference plane 140 to form angle b 214. In some examples, the sum of angle b 214 and pierce angle p 208 may be 90 degrees. As shown in FIG. 2, reference line 206a is parallel to surface 206 and orthogonal to vertical reference plane 140. Accordingly, angle a 216 between reference line 206a and extrapolated first dimension 136 may be equal to pierce angle p 208. The following equations may thus describe the relationship between angle a 216, angle b 214, and pierce angle p 208:

p=a (Eq. 1)

a+b=90° (Eq. 2)

b=90°−p (Eq. 3)

Thus, based on the foregoing, angle b may be a function of pierce angle p 208. In some examples, pierce angle p 208 may be between 5 and 50 degrees. In some examples, pierce angle p 208 may be between 10 and 30 degrees. In some examples, pierce angle p 208 may be between 15 and 25 degrees. In some examples, pierce angle p 208 may be between 20 and 40 degrees. In some examples, pierce angle p 208 may be between 45 and 90 degrees. In some examples, pierce angle p 208 may be between 0 and 90 degrees. In a specific example, pierce angle p 208 may be 20 degrees.

Returning now to FIGS. 1A-B, pierce electrodes 106 may be positioned such that second dimension 132 of angled surface 138 of each pierce electrode 106 forms angle 134 (shown in FIG. 1A) with respect to horizontal reference plane 150. In some examples, angle 134 may be such that the portion of ion beam path 102 between pierce electrodes 106 is approximately perpendicular to second dimension 132 of the angled surface. Thus, the ion beam may be perpendicular to second dimension 132 as the ion beam passes between pierce electrodes 106 along ion beam path 102. In some examples, angle 134 may be between 35 and 65 degrees. In other examples, angle 134 may be between 45 degrees and 55 degrees. In yet other examples, angle 134 may be between 50 degrees and 53 degrees.

As described above, ion beam path 102 may be curvilinear. Specifically, ion beam path 102 may have an “S-shaped” trajectory. The electrodes along ion beam path 102 may be configured to deflect an ion beam such that the ion beam follows the curvilinear “S-shaped” trajectory. In some examples, electrode assembly 100 may include a first set of electrodes configured to deflect the ion beam a first amount with respect to horizontal reference plane 150 as the ion beam travels along ion beam path 102 from opening 118 to pierce electrodes 106. The first set of electrodes may be disposed between opening 118 and pierce electrodes 106. In this example, the first set of electrodes may include at least two of electrodes 112, 122, 124, and 125. Thus, at least two of electrodes 112, 122, 124, and 125 may function to deflect the ion beam the first amount with respect to horizontal reference plane 150 such that the ion beam is directed from opening 118 up toward pierce electrodes 106. It should be recognized that in other examples, the shape, size, and position of the first set of electrodes may vary.

In some examples, electrode assembly 100 may further include a second set of electrodes configured to deflect the ion beam a second amount with respect to horizontal reference plane 150 as the ion beam travels along ion beam path 102 from the first set of electrodes to opening 120. The second set of electrodes may be disposed between the first set of electrodes and opening 120. In this example, the second set of electrodes may include at least two of electrodes 114, 115, 122, and 123. Thus, at least two of electrodes 114, 115, 122, and 123 may function to deflect the ion beam the second amount with respect to horizontal reference plane 150 such that the ion beam is substantially parallel to horizontal reference plane 150 as it exits opening 120. It should be recognized that in other examples, the shape, size, and position of the second set of electrodes may vary.

The “S-shaped” trajectory of ion beam path 102 may be advantageous for reducing charge contamination in the ion beam. Specifically, neutral species in the ion beam would not be deflected by the first set of electrodes and the second set of electrodes and thus would be filtered out from the ion beam along ion beam path 102. Accordingly, only ions in the ion beam may traverse electrode assembly 100 along ion beam path 102, thereby reducing charge contamination in the ion beam.

As shown in FIGS. 1A-B, electrode assembly 100 may further include terminal electrodes 110 and suppression electrodes 124. Terminal electrodes 110 may define at least part of openings 116 and 118. Suppression electrodes 124 may be adjacent to terminal electrodes and may function to repel electrons in the ion beam from entering electrode assembly 100. For example, a negative voltage with respect to ground potential may be applied to suppression electrodes 124 to repel electrons from entering openings 116 and 118.

In some examples, electrode assembly 100 may be configured to decelerate or accelerate a ribbon-shaped ion beam. A ribbon-shaped ion beam may refer to an ion beam having an elongated cross-section where a first dimension of the cross-section is greater than a second dimension of the cross-section. The first dimension of the cross-section may be perpendicular to the second dimension of the cross-section. In some examples, the first dimension of the cross-section may be at least 300 mm. In some examples, ion beam paths 102 and 104 may each be configured to allow the ribbon-shaped ion beam to pass through electrode assembly 100. Further, in some examples, first dimension 126 of opening 120 may be at least twice as large as second dimension 128 of opening 120. In some examples, first dimension 126 of opening 120 may be at least 300 mm. Openings 116 and 118 may be similarly configured as opening 120 where each of openings 116 and 118 may have a first dimension that is at least twice as large as a second dimension.

In some examples, exit electrodes 108 and pierce electrodes 106 may be configured such that a ribbon-shaped ion beam oriented with its first dimension approximately parallel to horizontal reference plane 150 may pass between exit electrodes 108 and pierce electrodes 106. In particular, the distance between pierce electrodes 106 may be greater than the distance between exit electrodes 108. In a specific example, the distance between pierce electrodes 106 may be at least twice as large as the distance between exit electrodes 108. Further, in some examples, the distance between pierce electrodes 106 may be greater than the diameter of the work piece to be implanted. In a specific example, the distance between pierce electrodes 106 may be at least 300 mm.

It should be appreciated that electrode assembly 100 may include other components and that some components described above may be optional. For instance, in some examples, electrode assembly 100 may include additional or fewer electrodes. In other examples, electrode assembly may include only one of ion beam path 102 or 104. Further, it should be recognized that the electrodes of electrode assembly 100, including pierce electrodes 106, may be coupled to one or more voltage sources. Thus, the electrodes of electrode assembly 100 may generate, using the one or more voltage sources, suitable electric fields to manipulate the ion beam along ion beam path 102 or 104. In particular, a voltage source may be used to apply a voltage to pierce electrodes 106 to generate a suitable electric field along the boundary of the ion beam to resist divergence of the ion beam between exit electrodes 108.

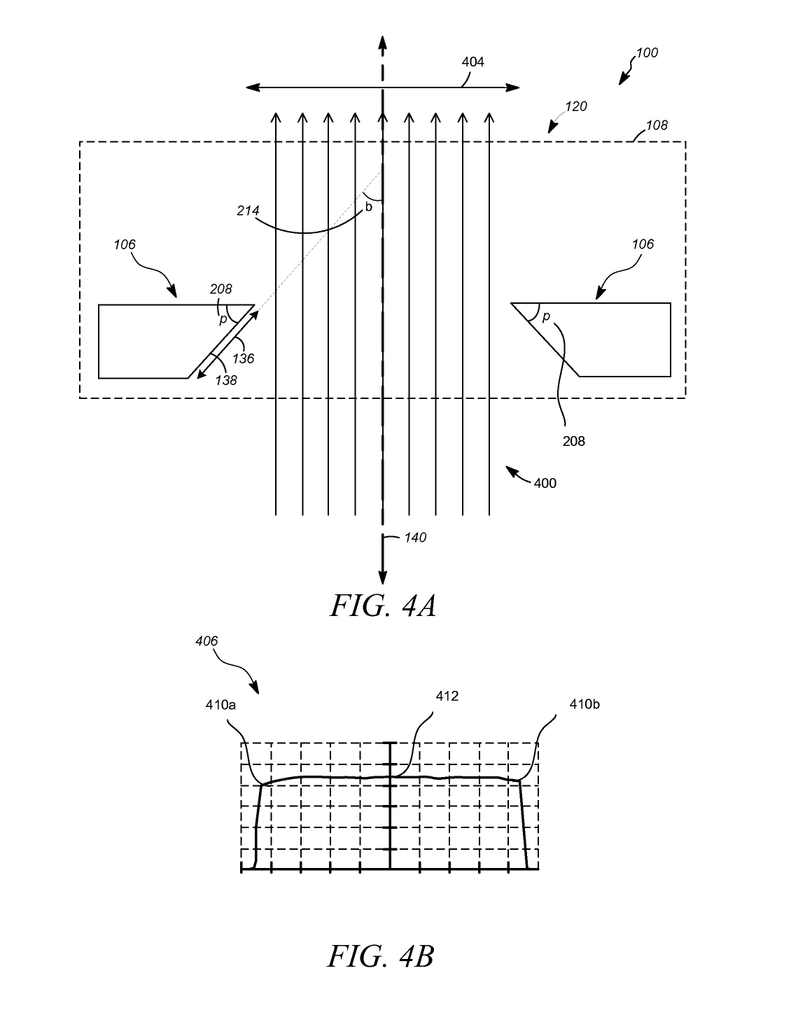

Turning now to FIG. 4A, an angled top-down perspective view of ion beam 400 passing through a portion of electrode assembly 100 is depicted. For simplicity, only a portion of electrode assembly 100 is depicted. The perspective view of FIG. 4A may correspond to view angle 130 depicted in FIG. 1A. As shown, ion beam 400 may remain substantially collimated as it passes between pierce electrodes 106 and exit electrodes 108 and after it exits opening 120. Further, the beam density of ion beam 400 exiting through opening 120 may be substantially uniform across dimension 404 of ion beam 400. FIG. 4B illustrates ion beam profile 406 of ion beam 400 along dimension 404 after ion beam 400 exits opening 120. As shown in FIG. 4B, ion beam profile 406 may be substantially uniform where the beam density at left edge region 410a, center region 412, and right edge region 410b of ion beam profile 406 are substantially equal. In semiconductor fabrication, performing ion implantation using a collimated ion beam having a uniform beam density may be desirable for achieving superior dopant uniformities and robust process repeatability. Accordingly, ion beam 400 may be suitable for performing ion implantation in semiconductor fabrication.

In some examples, ion beam 400 described with respect to FIGS. 4A-B may be achieved by applying a suitable voltage to pierce electrodes 106 and positioning angled surface 138 of each pierce electrode 106 at suitable angle b 214. In particular, when a suitable voltage is applied and angled surface 138 of each pierce electrode 106 is positioned at a suitable angle b 214, pierce electrodes 106 may generate a suitable electric field along the boundary of ion beam 400 to achieve collimated ion beam 400 with uniform beam density depicted in FIG. 4A. The electric potential applied to pierce electrodes 106 may be between 0.5 and 10 kV, between 1 and 8 kV, or between 2 and 5 kV.

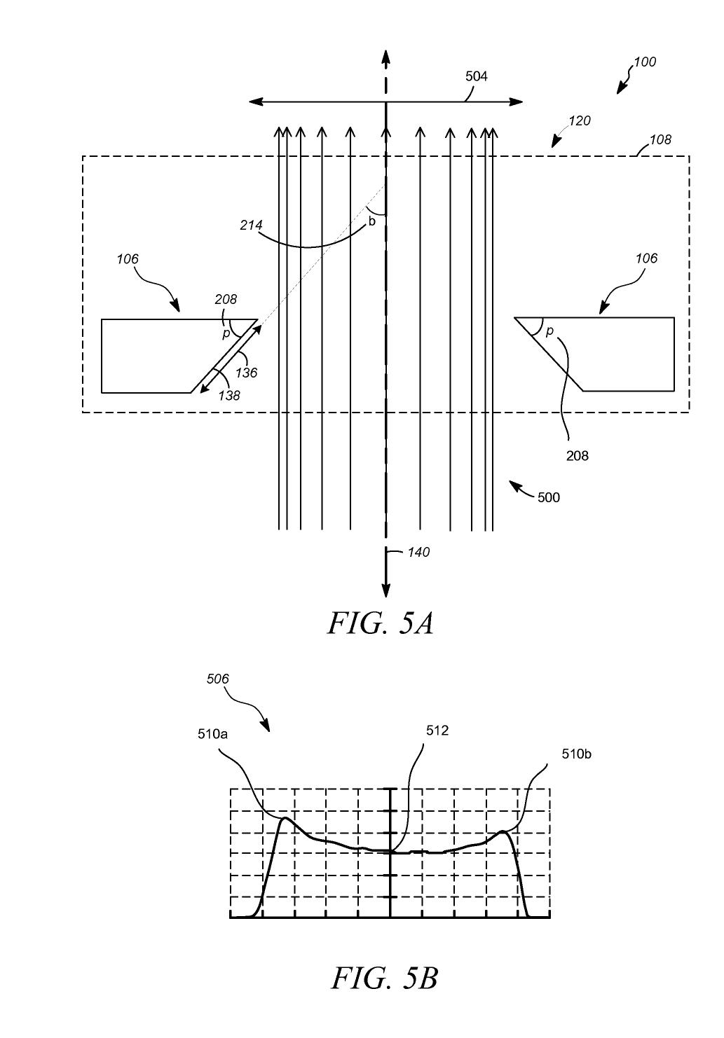

Turning now to FIG. 5A, an angled top-down perspective view of ion beam 500 passing through a portion of electrode assembly 100 is depicted. As in FIG. 4A, the perspective view of FIG. 5A may correspond to view angle 130 depicted in FIG. 1. As shown, ion beam 500 may remain substantially collimated as it passes through pierce electrodes 106 and exit electrodes 108 and after it exits opening 120. However, in this example, the beam density of ion beam 500 exiting opening 120 may be non-uniform along dimension 504 of ion beam 500. FIG. 5B illustrates ion beam profile 506 of ion beam 500 along dimension 504 after ion beam 500 exits opening 120. As shown in FIG. 5B, ion beam profile 506 may exhibit a non-uniform “horned” profile where the beam density at left edge region 510a and right edge region 510b of ion beam 500 are significantly greater than the beam density at center region 512 of ion beam 500. The poor beam density uniformity of ion beam 500 may be caused by at least one of an unsuitable voltage applied to pierce electrodes 106 and an unsuitable angle b 214 at which angled surface 138 of each pierce electrode 106 is positioned. Performing ion implantation using ion beam 500 may result in poor dopant uniformities and poor process control. Accordingly, ion beam 500 may not be suitable for performing ion implantation in semiconductor fabrication.

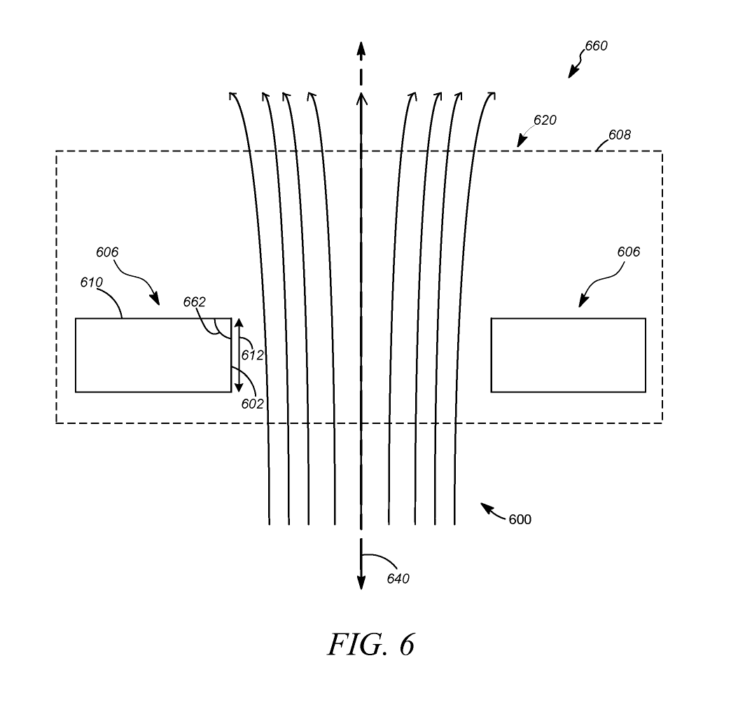

Turning now to FIG. 6, an angled top-down perspective view of ion beam 600 passing between electrodes 606 of electrode assembly 660 is depicted. For simplicity, only a portion of electrode assembly 660 that includes electrodes 606, exit electrodes 608, and opening 620 is depicted in FIG. 6. Electrode assembly 660 may be similar to electrode assembly 100 except that electrode assembly 660 does not include pierce electrodes 106. Instead, electrodes 606 take the place of pierce electrodes 106. Vertical reference plane 640 may be similar or identical to vertical reference plane 140 described in FIGS. 1A, 2, 4A, and 5A. Electrodes 606 may be similarly positioned as pierce electrodes 106. However, as shown in FIG. 6, surface 602 of each electrode 606 may be positioned differently from surface 138 of each pierce electrode 106. Specifically, dimension 612 of surface 602 may be approximately parallel to vertical reference plane 640. In other words, dimension 612 may form an angle of approximately 0 degrees with respect to vertical reference plane 640. Further, angle 662 of surface 602 with respect to surface 610 may be approximately 90 degrees. In this example, electrodes 606 may not be capable of generating a suitable electric field along the boundary of ion beam 600 to resist divergence of ion beam 600 between exit electrodes 608. Thus, as shown in FIG. 6, ion beam 600 may begin to diverge between exit electrodes 608 and may diverge significantly as it exits opening 620. Ion beam 600 may not be suitable for performing ion implantation in semiconductor fabrication.

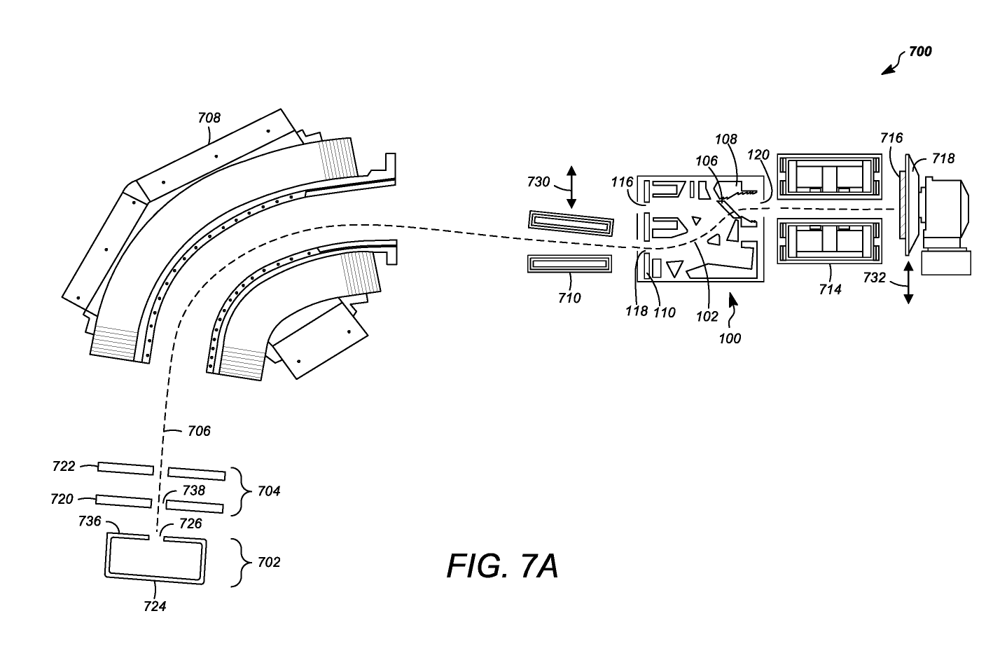

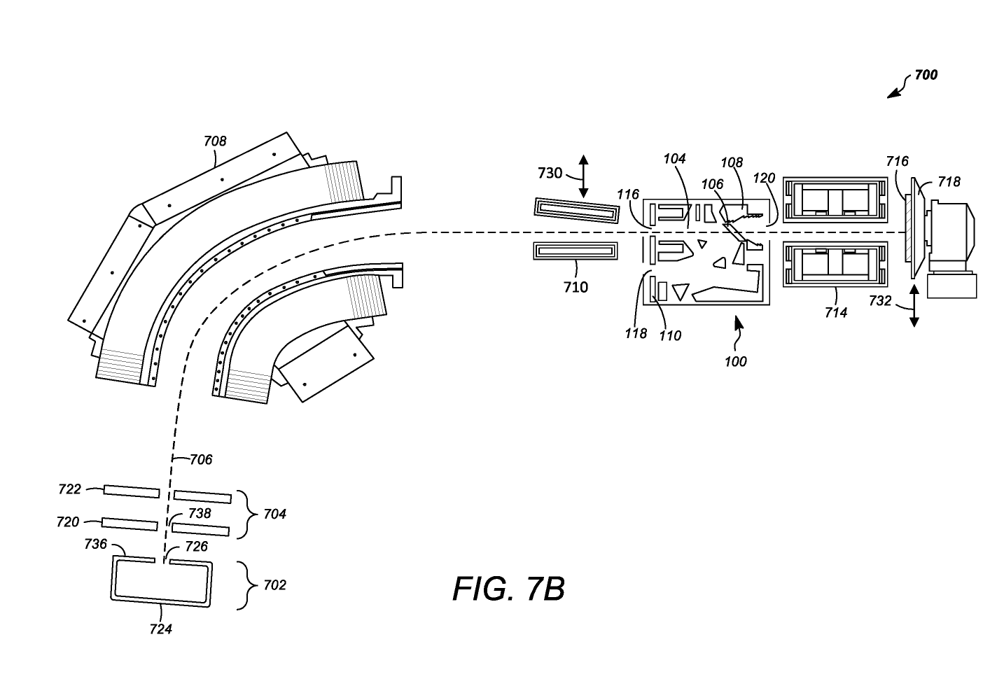

In some examples, electrode assembly 100 may be implemented in an ion beam implantation system to accelerate or decelerate an ion beam. For example, FIGS. 7A-B illustrate cross-sectional views of exemplary ion beam implantation system 700 implementing electrode assembly 100 to accelerate or decelerate an ion beam. System 700 may be configured to implant ions into work piece 716. In particular, system 700 may be used to perform ion implantation in semiconductor fabrication.

As shown in FIGS. 7A-B, system 700 may include ion source 702 and extraction manipulator 704 for generating ion beam 706. Extraction manipulator 704 may extract ion beam 706 from ion source 702 and direct ion beam 706 into mass analyzer 708 where ion beam 706 may be filtered by mass, charge, and energy. Ion beam 706 may be further directed through multipole magnets 710 and electrode assembly 100 and multipole magnets 714 to adjust the energy, shape, direction, angle, and uniformity of ion beam 706. In particular, electrode assembly 100 may function to adjust the energy of ion beam 706, remove neutral species from ion beam 706, and adjust the size, shape, and uniformity of ion beam 706. Multipole magnets 710 and 714 may function to adjust the uniformity, center angle, and divergence angle of ion beam 706. System 700 may further include work piece support structure 718, which may be configured to position work piece 716 in the path of ion beam 706, thereby causing implantation of ions into work piece 716.

Ion source 702 may be configured to generate ions of a desired species. For example, for semiconductor device fabrication, desired ion species may include boron, phosphorus, or arsenic (e.g., B+, P+, and As+). In some examples, ion source 702 may comprise a Bernas source, a Freeman source, or an indirectly heated cathode source. Ion source 702 may include arc chamber 724 that may be configured to receive one or more process gases from one or more gas sources (not shown). Ion source 702 may be configured to form a plasma in arc chamber 724 by electron ionization of the one or more process gases. In this example, ion source 702 may include a cathode (not shown) disposed within arc chamber 724. The cathode may include a filament that may be heated to generate electrons for ionizing the one or more process gases. The cathode may be coupled to a power source (not shown), which may bias the cathode at an arc voltage to accelerate the electrons from the cathode to the sidewalls of arc chamber 724. The energized electrons may ionize the one or more process gases in arc chamber 724, thereby forming a plasma in arc chamber 724.

Ion source 702 may include faceplate 736 on one side of arc chamber 724. Faceplate 736 may include exit aperture 726 through which ions extracted from ion source 702 may exit arc chamber 724. In this example, exit aperture 726 may be a slit or a slot for forming a ribbon-shaped ion beam 706. In other examples, exit aperture 726 may be a hole or a set of holes for forming a spot ion beam. Faceplate 736 may be coupled to a power source (not shown) to bias faceplate 736, thereby creating a potential difference (e.g., extraction voltage) between ion source 702 and extraction manipulator 704 to generate ion beam 706.

Extraction manipulator 704 may include suppression electrode 720 and ground electrode 722. A power supply (not shown) may be coupled to suppression electrode 720 to apply a suppression voltage to suppression electrode 720. Suppression electrode 720 may function to resist electrons from flowing into ion source 702. Ground electrode 722 may be coupled to a ground potential. It should be recognized that, in other examples, extraction manipulator 704 may include additional electrodes that may be biased using one or more power supplies.

In some examples, the cross-section of ion beam 706 may have an x-dimension and a y-dimension. The x-dimension may be perpendicular to the y-dimension and both the x-dimension and the y-dimension may be perpendicular to the direction of travel of ion beam 706. In FIGS. 7A-B, the x-dimension of ion beam 706 may be parallel to the plane of the drawing while the y-dimension of ion beam 706 may be orthogonal to the plane of the drawing. In some examples, ion beam 706 may be a ribbon-shaped beam where the x-dimension is smaller than the y-dimension. In one such example, the y-dimension may be at least twice as large as the x-dimension. In other examples, ion beam 706 may be a spot beam where the x-dimension and the y-dimension are approximately equal.

Mass analyzer 708 may be configured to generate a magnetic field such that only the ions in ion beam 706 having a desired energy and mass-to-charge ratio may pass through mass analyzer 708 toward work piece 716. Mass analyzer 708 may be configured to direct ion beam 706 along one of two paths. As shown in FIG. 7A, mass analyzer 708 may direct ion beam 706 along a first path into opening 118 of electrode assembly 100 such that ion beam 706 travels through electrode assembly 100 along ion beam path 102 of electrode assembly 100. Alternatively, as shown in FIG. 7B, mass analyzer 708 may direct ion beam 706 along a second path into opening 116 of electrode assembly 100 such that ion beam 706 travels through electrode assembly 100 along ion beam path 104 of electrode assembly 100.

Multipole magnets 710 may include an array of coils arranged on ferromagnetic supports. Electrical energy may be supplied to the array of coils to generate a contiguous magnetic field. In particular, multipole magnets 710 may be configured such that electrical energy may be independently supplied to the individual coils such that the magnetic field gradient over the contiguous magnetic field may be adjusted. In this way, a suitable non-uniform magnetic field may be generated to adjust the size, shape, angle, and/or uniformity of ion beam 706. For example, a suitable magnetic field may be generated by multipole magnets 710 to control the size and current density of the ion beam 706. In doing so, multipole magnets 710 may be configured to adjust the shape of the beam as well as the spatial uniformity. Further, in some examples, multipole magnets 710 may be configured to generate a quadrupole magnetic field that may be suitable for adjusting the convergence or divergence angle of ion beam 706. It should be recognized that other variations of multipole magnets 710 are also possible.

In some examples, multipole magnets 710 may be configured to move along a track in a direction indicated by arrows 730. In this way, multipole magnets 710 may be positioned to receive ion beam 706 from mass analyzer 708 along each of the two paths described above. For example, as shown in FIG. 7A, multipole magnets 710 may be positioned to align with opening 118 of electrode assembly 100 when ion beam 706 is directed along the first path. Alternatively, as shown in FIG. 7B, multipole magnets 710 may be positioned to align with opening 116 of electrode assembly 100 when ion beam 706 is directed along the second path.

As described above with respect to FIGS. 1A-B, electrode assembly 100 may be configured to accelerate or decelerate ion beam 706. Electrode assembly 100 may be configured to accelerate ion beam 706 or allow ion beam 706 to drift at a constant velocity along ion beam path 104. Further, electrode assembly 100 may be configured to decelerate ion beam 706 along ion beam path 102. Ion beam 706 may pass between pierce electrodes 106 before exiting electrode assembly 100 via exit electrodes 108 and opening 120. As described above, pierce electrodes 106 may be configured to generate a suitable electric field along the boundary of ion beam 706 to resist ion beam 706 from diverging due to space charge effects. Thus, ion beam 706 may be substantially collimated as it exits electrode assembly 100.

Multipole magnets 714 may have a similar construction as multipole magnets 710 described above. In some examples, multipole magnets 714 may include fewer or additional coils compared to multipole magnets 710. In some examples, multipole magnets 714 may function to adjust the shape, direction, focus, and/or uniformity of ion beam 706. In addition, multipole magnets 714 may be configured to steer ion beam 706 to strike the surface of work piece 716 in a particular location, or to allow for other positional adjustments of ion beam 706. In other examples, multipole magnets 714 may be configured to repeatedly deflect ion beam 706 to scan work piece 716, which may be stationary or moving.

Work piece support structure 718 may be configured to position work piece 716 in front of ion beam 706, thereby causing ions to implant into work piece 716. In some examples, work piece support structure 718 may be configured to translate in one or more directions. For example, work piece support structure 718 may be configured to move work piece 716 with respect to ion beam 706 to scan ion beam 706 across work piece 716. More specifically, work piece support structure 718 may be configured to move work piece 716 in a direction (e.g., depicted by arrows 732) parallel to the x-dimension of ion beam 706. Further, work piece support structure 718 may be configured to rotate work piece 716.

In some examples, work piece support structure 718 may be configured to control the temperature of work piece 716. For example, the temperature of work piece 716 may be controlled by flowing heated or cooled gas onto the backside of work piece 716. In some examples, work piece support structure 718 may be configured to establish good thermal contact with work piece 716. In these examples, the temperature of work piece 716 may be controlled by controlling the temperature of work piece support structure 718. In some examples, work piece support structure 718 may be configured to be heated or cooled using fluid from a fluid heat exchanger. The temperature of work piece support structure 718 may thus be controlled by flowing heated or cooled fluid from the fluid heat exchanger. In other examples, work piece support structure 718 may include heating and cooling elements (e.g., thermoelectric elements, resistive heating elements, etc.) for controlling the temperature of work piece support structure 718.

Work piece 716 may comprise any suitable substrate used in the manufacturing of semiconductor devices, solar panels, or flat-panel displays. In examples where work piece 716 comprises a semiconductor substrate (e.g., silicon, germanium, gallium arsenide, etc.), work piece 716 may include semiconductor devices at least partially formed thereon.

It should be appreciated that suitable variations and modifications may be made to system 700. For instance, system 700 may include additional components such as additional electrodes and magnets for manipulating ion beam 706. Further, the position of multipole magnets 710 and 714 may vary. In some example, multipole magnets 714 may be disposed between multipole magnets 710 and electrode assembly 100. Further, in some examples, system 700 may include one or more variable apertures for controlling the current of ion beam 706. In one such example, a variable aperture may be disposed between mass analyzer 708 and electrode assembly 100.

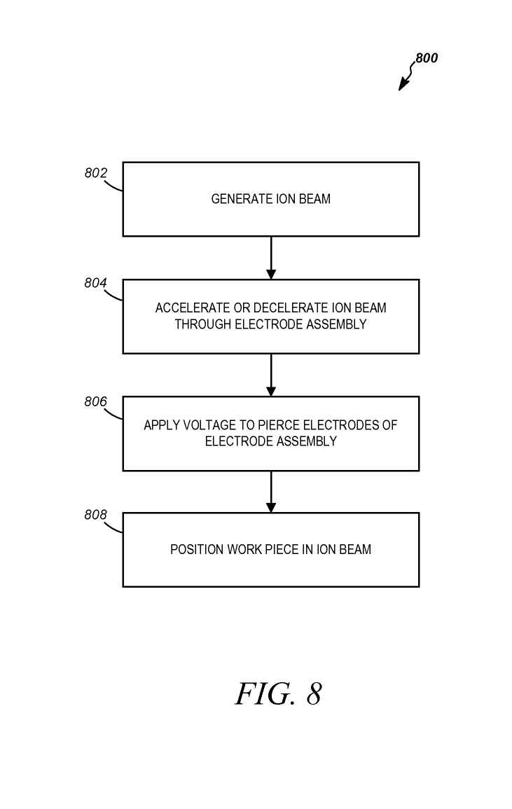

FIG. 8 illustrates process 800 for implanting ions into a work piece, according to various examples. Process 800 may be performed using ion beam implantation system 700, described above with reference to FIGS. 7A-B. Process 800 is described below with simultaneous reference to FIGS. 7A-B and FIG. 8.

At block 802 of process 800, ion beam 706 may be generated. In some examples, ion beam 706 may be generated using ion source 702 and extraction manipulator 704. Generating ion beam 706 using ion source 702 and extraction manipulator 704 may include forming a plasma from one or more process gases in arc chamber 724 to generate the desired ion species. Suitable voltages may be applied to faceplate 736, suppression electrode 720, and ground electrode 722 to extract ion beam 706 from ion source 702 at the desired energy level. For example, to generate ion beam 706 comprising positive ions, a positive potential relative to ground may be applied to faceplate 736. In addition, a negative potential relative to ground may be applied to suppression electrode 720 to repel electrons downstream of extraction manipulator 704 from flowing into ion source 702.

In some examples, ion beam 706 may be generated having an elongated ribbon-shaped cross-section. For example, as described above, the cross-section of ion beam 706 may have an x-dimension that is smaller than a y-dimension of ion beam 706. In some examples, the ratio of the y-dimension to the x-dimension of the cross-section of ion beam 706 at work piece 716 may be at least 3:1. In some examples, the y-dimension of ion beam 706 at work piece 716 may be at least 300 mm. In other examples, ion beam 706 may be a spot beam where the x-dimension is approximately equal to the y-dimension.

At block 804 of process 800, ion beam 706 may be accelerated or decelerated through electrode assembly 100. In some examples, ion beam 706 may be accelerated through electrode assembly 100 along ion beam path 104. In these examples, ion beam 706 may enter electrode assembly 100 through opening 116 at an initial energy, accelerate along ion beam path 104, and exit electrode assembly 100 through opening 120 at a final energy that is greater than the initial energy. In other examples, ion beam 706 may be decelerated through electrode assembly 100 along ion beam path 102. In these examples, ion beam 706 may enter electrode assembly 100 through opening 118 at an initial energy, decelerate along ion beam path 102, and exit electrode assembly 100 through opening 120 at a final energy that is lower than the initial energy.

In examples where ion beam 706 contains positive ions, ion beam 706 may be accelerated through electrode assembly 100 by applying a negative potential difference across electrode assembly 100. In one example, a negative potential difference may be applied by coupling exit electrodes 108 to ground potential and applying a positive voltage relative to ground potential to terminal electrodes 110. Conversely, in examples where ion beam 706 contains positive ions, ion beam 706 may be decelerated through electrode assembly 100 by applying a positive potential difference across electrode assembly 100. In one example, a positive potential difference may be applied by coupling exit electrodes 108 to ground potential and applying a negative voltage relative to ground potential to terminal electrodes 110.

In examples where ion beam 706 is decelerated through electrode assembly 100, process 800 may include deflecting ion beam 706 such that ion beam 706 follows the curvilinear ion beam path 102 through electrode assembly 100. In some examples, with reference to FIG. 1A, ion beam 706 may be deflected a first amount with respect to horizontal reference plane 150 as ion beam 706 travels along ion beam path 102 from opening 118 to pierce electrodes 106. Ion beam 706 may be deflected the first amount using the first set of electrodes of electrode assembly 100 described above. In some examples, the first set of electrodes may include at least two of electrodes 112, 122, 124, and 125 of electrode assembly 100. Further, in some examples, ion beam 706 may be deflected a second amount with respect to horizontal reference plane 150 as ion beam 706 travels along ion beam path 102 from the first set of electrodes of electrode assembly 100 to opening 120. Ion beam 706 may be deflected the second amount using the second set of electrodes of electrode assembly 100 described above. In some examples, the second set of electrodes may include at least two of electrodes 114, 115, 122, and 123 of electrode assembly 100.

At block 806 of process 800, a voltage may be applied to pierce electrodes 106. Ion beam 706 may pass between pierce electrodes 106 as ion beam 706 passes through electrode assembly 100 along ion beam paths 102 or 104. In some examples, with reference to FIG. 1A, ion beam 706 may be approximately perpendicular to second dimension 132 of angled surface 138 of each pierce electrode 106 as ion beam 706 passes between pierce electrodes 106 along ion beam path 102. As described above, pierce electrodes 106 may function to control space charge effects and thus resist space charge blow-up of ion beam 706. Applying the voltage to pierce electrodes 106 may be particularly desirable when ion beam 706 is decelerated along ion beam path 102 and enters exit electrodes 108 having high current and low energy. In some examples, the voltage applied to pierce electrodes 106 may cause pierce electrodes 106 to generate an electric field along the boundary of ion beam 706 to resist divergence of ion beam 706 between exit electrodes 108. As a result, ion beam 706 may remain collimated as it passes between exit electrodes 108 and exits electrode assembly 100. In some examples, the voltage applied to the pierce electrodes 106 may be between 0 kV and 10 kV. In other examples, the voltage applied to the pierce electrodes 106 may be between 1 kV and 8 kV. In yet other examples, the voltage applied to the pierce electrodes 106 may be between 2 kV and 5 kV.

At block 808 of process 800, work piece 716 may be positioned in ion beam 706 to implant ions into work piece 716. For example, work piece 716 may be positioned using work piece support structure 718 such that ion beam 706 impinges onto work piece 716, thereby causing ions to implant into work piece 716. In some examples, work piece support structure 718 may move work piece 716 relative to ion beam 706 to cause ion beam 706 to scan across work piece 716. Specifically, work piece support structure 718 may move work piece 716 in a direction (e.g., depicted by arrows 732) parallel to the x-dimension of ion beam 706. The scan speed of work piece 716 may be controlled using work piece support structure 718 to fine-tune the dose rate of ions implanted. Further, work piece support structure 718 may rotate work piece 716 to enable ions to implant uniformly into work piece 716.

Work piece 716 may comprise any suitable substrate used in the manufacturing of semiconductor devices, solar panels, or flat-panel displays. In examples where work piece 716 comprises a semiconductor substrate (e.g., silicon, germanium, gallium arsenide, etc.), work piece 716 may include semiconductor devices at least partially formed thereon. Further, work piece 716 may include a top-most mask layer. The mask layer may comprise a photo-resist layer or a hard mask layer (e.g., silicon nitride, silicon oxide, silicon oxynitride, silicon carbide, carbon, etc.)

While specific components, configurations, features, and functions are provided above, it will be appreciated by one of ordinary skill in the art that other variations may be used. Additionally, although a feature may appear to be described in connection with a particular example, one skilled in the art would recognize that various features of the described examples may be combined. Moreover, aspects described in connection with an example may stand alone.

Although embodiments have been fully described with reference to the accompanying drawings, it should be noted that various changes and modifications will be apparent to those skilled in the art. Such changes and modifications are to be understood as being included within the scope of the various examples as defined by the appended claims.

What is claimed is:

1. An electrode assembly for accelerating or decelerating an ion beam, the electrode assembly comprising:
a first ion beam path extending from a first opening of the electrode assembly to a second opening of the electrode assembly, wherein the first opening and the second opening are disposed on opposite sides of the electrode assembly;
a pair of exit electrodes defining a portion of the first ion beam path adjacent to the second opening, the pair of exit electrodes positioned on opposite sides of a first plane aligned with a first dimension of the second opening; and
a pair of pierce electrodes defining a portion of the first ion beam path adjacent to the pair of exit electrodes, the pair of pierce electrodes positioned on opposite sides of a second plane aligned with a second dimension of the second opening, wherein:
the second dimension of the second opening is perpendicular to the first dimension of the second opening;
each pierce electrode of the pair of pierce electrodes has an angled surface facing the first ion beam path; and
the angled surface of each pierce electrode is positioned such that a first dimension of the angled surface of each pierce electrode forms an angle of between 40 and 80 degrees with respect to the second plane.

2. The electrode assembly of claim 1, wherein the pair of pierce electrodes is positioned such that a second dimension of the angled surface of each pierce electrode forms an angle of between 35 and 65 degrees with respect to the first plane, and wherein the second dimension of the angled surface is perpendicular to the first dimension of the angled surface.

3. The electrode assembly of claim 1, wherein the pair of pierce electrodes is configured such that the first ion beam path gradually narrows between the pair of pierce electrodes toward the second opening.

4. The electrode assembly of claim 1, wherein the first ion beam path has an S-shaped trajectory.

5. The electrode assembly of claim 1, further comprising a first set of electrodes configured to deflect the ion beam a first amount with respect to the first plane as the ion beam travels along the first ion beam path from the first opening to the pair of pierce electrodes.

6. The electrode assembly of claim 5, further comprising a second set of electrodes configured to deflect the ion beam a second amount with respect to the first plane as the ion beam travels along the first ion beam path from the first set of electrodes to the second opening.

7. The electrode assembly of claim 1, wherein the pair of pierce electrodes is configured to apply an electric field along a boundary of the ion beam to resist divergence of the ion beam between the pair of exit electrodes.

8. The electrode assembly of claim 1, further comprising a third opening disposed on a same side as the first opening, wherein a second ion beam path extends from the third opening to the second opening, and wherein the third opening is aligned with respect to the second opening such that the second ion beam path has a straight trajectory that is approximately parallel to the first plane.

9. The electrode assembly of claim 1, wherein the first ion beam path is configured to allow a ribbon-shaped ion beam to pass through the electrode assembly, and wherein a dimension of a cross-section of the ribbon-shaped ion beam is greater than 300 mm.

10. The electrode assembly of claim 1, wherein the first dimension of the second opening is greater than 300 mm, and wherein the first dimension of the second opening is at least twice as large as the second dimension of the second opening.

11. An ion beam implantation system for implanting ions into a work piece, the system comprising:
an ion source;
an extraction manipulator configured to generate an ion beam by extracting ions from the ion source;
an electrode assembly configured to accelerate or decelerate the ion beam, the electrode assembly comprising:
a first ion beam path extending from a first opening of the electrode assembly to a second opening of the electrode assembly, wherein the first opening and the second opening are disposed on opposite sides of the electrode assembly;
a pair of exit electrodes defining a portion of the first ion beam path adjacent to the second opening, the pair of exit electrodes positioned on opposite sides of a first plane aligned with a first dimension of the second opening; and
a pair of pierce electrodes defining a portion of the first ion beam path adjacent to the pair of exit electrodes, the pair of pierce electrodes positioned on opposite sides of a second plane aligned with a second dimension of the second opening, wherein:
the second dimension of the second opening is perpendicular to the first dimension of the second opening;
each pierce electrode of the pair of pierce electrodes has an angled surface facing the first ion beam path; and
the angled surface of each pierce electrode is positioned such that a first dimension of the angled surface of each pierce electrode forms an angle of between 40 and 80 degrees with respect to the second plane; and
a work piece support structure configured to position the work piece in the ion beam, thereby implanting ions into the work piece.

12. The system of claim 11, wherein the pair of pierce electrodes is positioned such that a second dimension of the angled surface of each pierce electrode forms an angle of between 35 and 65 degrees with respect to the first plane, and wherein the second dimension of the angled surface is perpendicular to the first dimension of the angled surface.

13. The system of claim 11, wherein the pair of pierce electrodes is configured such that the first ion beam path gradually narrows between the pair of pierce electrodes toward the second opening.

14. The system of claim 11, wherein the first ion beam path has an S-shaped trajectory.

15. The system of claim 11, wherein the electrode assembly further comprises a first set of electrodes configured to deflect the ion beam a first amount with respect to the first plane as the ion beam travels along the first ion beam path from the first opening to the pair of pierce electrodes.

16. The system of claim 15, wherein the electrode assembly further comprises a second set of electrodes configured to deflect the ion beam a second amount with respect to the first plane as the ion beam travels along the first ion beam path from the first set of electrodes to the second opening.

17. The system of claim 11, wherein the pair of pierce electrodes is configured to apply an electric field along a boundary of the ion beam to resist divergence of the ion beam between the pair of exit electrodes.

18. The system of claim 11, wherein the electrode assembly further comprises a third opening disposed on a same side as the first opening, wherein a second ion beam path of the electrode assembly extends from the third opening to the second opening, and wherein the third opening is aligned with respect to the second opening such that the second ion beam path has a straight trajectory that is approximately parallel to the first plane.

19. A method for implanting ions into a work piece using an ion implantation system comprising an electrode assembly having pierce electrodes, the method comprising:
generating an ion beam;
decelerating the ion beam through the electrode assembly, the electrode assembly comprising:
a first ion beam path extending from a first opening of the electrode assembly to a second opening of the electrode assembly, wherein the first opening and the second opening are disposed on opposite sides of the electrode assembly;
a pair of exit electrodes defining a portion of the first ion beam path adjacent to the second opening, the pair of exit electrodes positioned on opposite sides of a first plane aligned with a first dimension of the second opening; and
a pair of pierce electrodes defining a portion of the first ion beam path adjacent to the pair of exit electrodes, the pair of pierce electrodes positioned on opposite sides of a second plane aligned with a second dimension of the second opening, wherein:
the second dimension of the second opening is perpendicular to the first dimension of the second opening;
the pair of pierce electrodes each have an angled surface facing the first ion beam path;
the angled surface of each pierce electrode is positioned such that a first dimension of the angled surface of each pierce electrode forms an angle of between 40 and 80 degrees with respect to the second plane; and
the ion beam enters the electrode assembly through the first opening at a first energy, decelerates along the first ion beam path, and exits the electrode assembly through the second opening at a second energy that is lower than the first energy; and
positioning the work piece in the ion beam to implant ions into the work piece.

20. The method of claim 19, further comprising:
applying a voltage to the pair of pierce electrodes, wherein the pair of pierce electrodes generates an electric field along a boundary of the ion beam adjacent to the pair of pierce electrodes to resist divergence of the ion beam between the pair of exit electrodes.

21. The method of claim 20, wherein the voltage applied to the pair of pierce electrodes is between 0.5 kV and 10 kV.

22. The method of claim 19, wherein the pair of pierce electrodes is configured such that the first ion beam path gradually narrows between the pair of pierce electrodes towards the second opening.

23. The method of claim 19, wherein the pair of pierce electrodes is positioned such that a second dimension of the angled surface of each pierce electrode forms an angle of between 35 and 65 degrees with respect to the first plane, and wherein the second dimension of the angled surface is perpendicular to the first dimension of the angled surface.

24. The method of claim 23, wherein the ion beam is approximately perpendicular to the second dimension of the angled surface as the ion beam passes between the pair of pierce electrodes.

25. The method of claim 19, wherein the first ion beam path has an S-shaped trajectory.

26. The method of claim 19, further comprising:
deflecting, using a first set of electrodes of the electrode assembly, the ion beam a first amount with respect to the first plane as the ion beam travels along the first ion beam path from the first opening to the pair of pierce electrodes.

27. The method of claim 26, further comprising:
deflecting, using a second set of electrodes of the electrode assembly, the ion beam a second amount with respect to the first plane as the ion beam travels along the first ion beam path from the first set of electrodes to the second opening.
